(19) United States
(12) Patent Application Publication
(10) Pub. No.: US 2013/0320372 A1
(43) Pub. Date: Dec. 5, 2013

(54) LIGHT EMITTING DIODE AND METHOD FOR MANUFACTURING THE SAME

(71) Applicant: LEXTAR ELECTRONICS CORPORATION, Hsinchu (TW)

(72) Inventor: Kun-Fu Huang, Miaoli County (TW)

(73) Assignee: LEXTAR ELECTRONICS CORPORATION, Hsinchu (TW)

(21) Appl. No.: 13/784,899

(22) Filed: Mar. 5, 2013

(30) Foreign Application Priority Data
Jun. 5, 2012 (TW) 101120183

(51) Int. Cl. H01L 33/58

(52) U.S. Cl. CPC H01L 33/58
USPC 257/98; 438/29

(57) ABSTRACT

A light emitting diode, comprising a light emitting diode (LED) cell, a dielectric layer and a metal layer is provided. The LED cell has a top surface, a bottom surface, a first lateral surface and a second lateral surface. The bottom surface is opposite to the top surface. The second lateral surface is opposite to the first lateral surface. An electrode layer is disposed on the top surface. The dielectric layer is disposed on the bottom surface, the first lateral surface and the second lateral surface. The metal layer is disposed on the dielectric layer and electrically insulated from the electrode layer.

This application claims the benefit of Taiwan application Serial No. 101120183, filed Jun. 5, 2012, the subject matter of which is incorporated herein by reference.

### BACKGROUND OF THE INVENTION

1. Field of the Invention

The invention relates in general to a light emitting diode (LED) and method for manufacturing the same, and more particularly to an LED with reduced cracking degree of elements and a method for manufacturing the same.

2. Description of the Related Art

Along with the rise in environmental awareness, energy saving and power reduction have become a significant issue nowadays. In comparison to conventional incandescent lamps, light emitting diode (LED) is more power saving and has been widely used in everydayness such as traffic signals, motorcycle tail lights, car headlights, street lights, computer indicator lights, flashlights, screen backlight modules. Normally, these luminous devices require an LED chip process and a packaging process.

In the LED packaging process, LED cells are fixed in a plastic cup and then are packaged with an encapsulant. However, the light generated by LED cells is scattered. When the scattered light radiates on the plastic cup or the encapsulant formed by resin, the plastic cup or the encapsulant may be deteriorated and the light-output efficiency and lifespan of the packaged LED may be affected.

### SUMMARY OF THE INVENTION

The invention is directed to a light emitting diode (LED) and method for manufacturing the same. A dielectric layer covers a bottom surface, a first lateral surface and a second lateral surface of the LED cell, and a metal layer is disposed on the dielectric layer to maintain upward output of the LED light and avoid the encapsulant being radiated and deteriorated.

According to one embodiment of the present invention, a light emitting diode, comprising a light emitting diode (LED) cell, a dielectric layer and a metal layer is provided. The LED cell has a top surface, a bottom surface, a first lateral surface and a second lateral surface. The bottom surface is opposite to the top surface. The second lateral surface is opposite to the first lateral surface. An electrode layer is disposed on the top surface. The dielectric layer is disposed on the bottom surface, the first lateral surface and the second lateral surface. The metal layer is disposed on the dielectric layer and electrically insulated from the electrode layer.

According to another embodiment of the present invention, a manufacturing method of light emitting diode is provided. The method comprises the following steps. A wafer whose surface has a plurality of adjacent LED cells is provided, wherein each LED cell has a top surface, a bottom surface, a first lateral surface and a second lateral surface, the bottom surface is opposite to the top surface, the second lateral surface is opposite to the first lateral surface, and an electrode layer is disposed on the top surface. An extendable adhesive is provided, and the wafer is turned over so that an extendable adhesive is conformably pasted on the top surface of each LED cell on the wafer. A cutting process is performed, so that the adjacent LED cells are separated from each other. The extendable adhesive is extended, so that the interval between separate LED cells is increased to a distance d, wherein d>0. A dielectric layer is formed on the bottom surface, the first lateral surface and the second lateral surface of the LED cells separated by the distance d. A metal layer electrically insulated from the electrode layer is formed on the dielectric layer.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1˜4 are cross-sectional views of the procedures for manufacturing a light emitting diode according to an embodiment of the invention; and

FIG. 5 shows a schematic diagram of an LED cell manufactured according to an embodiment of the invention.

### DETAILED DESCRIPTION OF THE INVENTION

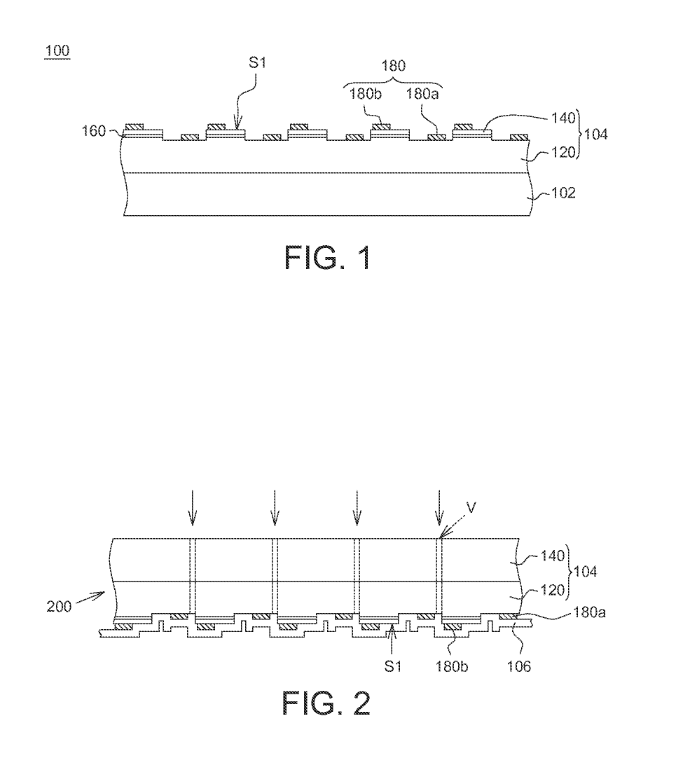

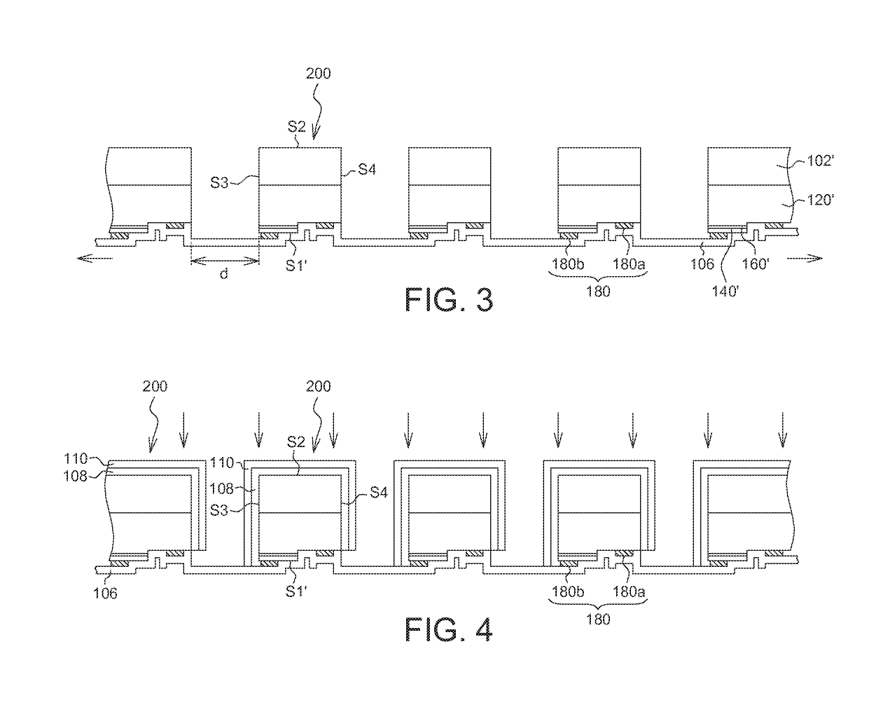

FIGS. 1˜4 are cross-sectional views of the procedures for manufacturing a light emitting diode according to an embodiment of the invention. In the present embodiment, the cross-section of the wafer 100 may be extended to both sides. For convenience of illustration, only partial of the wafer 100 is illustrated in FIGS. 1˜4, and the extension part is denoted by an interruption.

Referring to FIG. 1, a surface of wafer 100 has a plurality of adjacent LED cells. The wafer 100 comprises a substrate 102, an epitaxial layer 104 and an active layer 160. The substrate 102 is realized by such as a sapphire substrate. The epitaxial layer 104 is such as gallium nitride (GaN) with doped material. In greater details, the epitaxial layer 104 comprises a first doping layer 120 and a second doping layer 140. The first doping layer 120 is realized by such as an n-type doping layer, and the second doping layer 140 is realized by such as a p-type doping layer. For example, the first doping layer 120 such as has silicon doped in the gallium nitride layer, and the second doping layer 140 such as has magnesium doped in the gallium nitride layer. The first doping layer 120 is disposed on the substrate 102. The active layer 160 is formed on partial surface of the first doping layer 120. The second doping layer 140 is disposed on a surface of the active layer 160.

An element isolation (MESA) process is performed to etch partial of the epitaxial layer 104 and the active layer 160 until the etched surface of the epitaxial layer 104 exposes partial of the top surface of the first doping layer 120, and the exposed top surface of the first doping layer 120 is lower than the exposed top surface of the second doping layer 140. Then, an electrode layer 180 comprising a first electrode (negative polarity) and a second electrode (positive polarity) is formed on a top surface of the etched epitaxial layer 104. For example, the conductive pad 180a is used as negative polarity and the conductive pad 180b is used as positive polarity.

As indicated in FIG. 1, the conductive pad 180a is disposed on the exposed top surface of the first doping layer 120, and the conductive pad 180b is disposed on the exposed top surface of the second doping layer 140.

In the present embodiment, the top surface S1 of the wafer 100 comprises the top surfaces of the first doping layer 120 and the second doping layer 140 which are interlaced with each other, and the surfaces of the conductive pad 180a and the conductive pad 180b respectively disposed on the top surfaces of the first doping layer 120 and the second doping layer 140.

Referring to FIG. 2, an extendable adhesive 106 is provided and the wafer 100 is turned over, so that an extendable adhesive 106 is conformably pasted on the top surface S1 of each LED cell on the wafer 100. Examples of the extendable adhesive 106 include blue tape or other adhesive film that can be extended by a force. Then, a cutting process is performed to separate adjacent LED cells 200 from each other. In the cutting process, the LED cells are cut along a plurality of cutting positions V by way of laser, wheel knife or punching (die cutting).

Referring to FIG. 3, a force substantially parallel to the surface of the adhesive 106 is applied to extend the adhesive 106, so that the adhesive 106 is extended along a direction parallel to the surface of the adhesive 106. Thus, the interval between separate LED cells 200 is increased to a distance d, wherein d is larger than 0. As indicated in FIG. 3, each separate light emitting diode 200 has a top surface S1′, a bottom surface S2, a first lateral surface S3 and a second lateral surface S4. The bottom surface S2 is opposite to the top surface S1′, the second lateral surface S4 is opposite to the first lateral surface S3, and the electrode layer 180 is disposed on the top surface S1′.

Referring to FIG. 4, a dielectric layer 108 is formed on the bottom surface S2, the first lateral surface S3 and the second lateral surface S4 of each separate LED cell 200. In an embodiment, the dielectric layer 108 may be formed by the chemical vapor deposition process, and the dielectric layer 108 may comprise silicon oxide or silicon nitride or nitrogen oxide silicide. Then, a metal layer 110 electrically insulated from the electrode layer 180 is formed on the dielectric layer 108. In an embodiment, the metal layer 110 comprising one of silver, gold and aluminum or an alloy thereof may be formed by the physical vapor deposition (such as sputtering or vapor deposition). In an embodiment, the adhesive 106 is removed to obtain a plurality of LED cells 200 covered by the dielectric layer 108 and the metal layer 110.

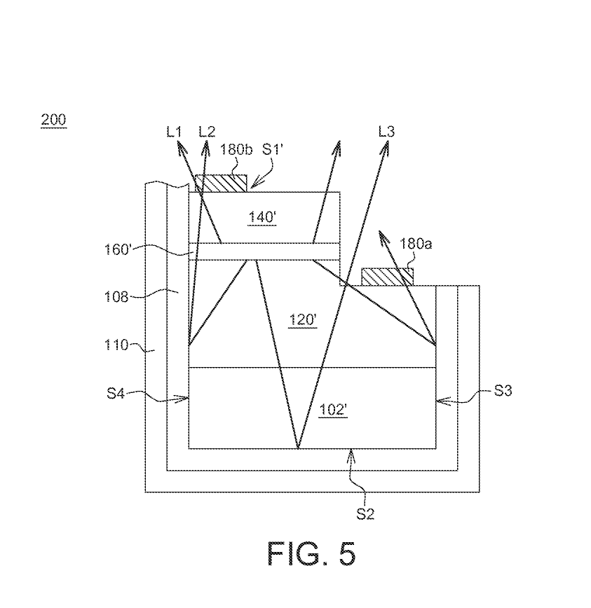

FIG. 5 shows a schematic diagram of an LED cell 200 manufactured according to an embodiment of the invention. Referring to FIG. 5. The LED cell 200 has a top surface S1′, a bottom surface S2, a first lateral surface S3 and a second lateral surface S4. The LED cell 200 sequentially comprises a substrate 102′, a first doping layer 120′, an active layer 160′ and a second doping layer 140′ in a direction from the bottom surface S2 heading towards the top surface S1′. The electrode layer is disposed on the top surface S1′, and comprises a first electrode (negative polarity) and a second electrode (positive polarity). For example, the conductive pad 180a is used as negative polarity and the conductive pad 180b is used as positive polarity. The conductive pad 180a is disposed on the surface of the first doping layer 120′ not covered by the active layer 160′. The conductive pad 180b is disposed on the surface of the second doping layer 140′. The dielectric layer 108 is disposed on the bottom surface S2, the first lateral surface S3 and the second lateral surface S4. The metal layer 110 is disposed on the dielectric layer 108 and electrically isolated from the conductive pad 180a and the conductive pad 180b.

In the present embodiment, the LED cell 200 is covered by the dielectric layer 108 and the metal layer 110, and merely a light emitting area of the top surface S1′ is exposed. Of the light generated by the active layer 160′, the light L1 is emitted upwards, the light L2 is emitted to lateral sides, and the light L3 is emitted downwards. The lights are transmitted between the dielectric layer 108 and the metal layer 110 formed by materials with different indexes of refraction. The reflection of the light L1 and the light L2 is subjected to the total reflection angle. When the light-emitting angles of the light L1 and the light L2 are smaller than the total reflection angle, the light L1 and the light L2, after passing through the dielectric layer 108, are reflected by the metal layer 110 and then are guided to be emitted upwards to the outside.

According to the LED cell 200 disclosed in the above embodiments of the invention, the light generated by the active layer 160′ is guided to be emitted upwards without increasing machine cost or complexity in the manufacturing process as long as the non-light-emitting area of the top surface S1′ is covered by the dielectric layer 108 and the metal layer 110. The design of the invention avoids plastic packaging elements such as plastic cup or encapsulant being radiated and deteriorated or damaged by scattered light, maintains the light extraction efficiency, and prolongs the lifespan of LED.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light emitting diode (LED), comprising:
a LED cell having a top surface, a bottom surface, a first lateral surface and a second lateral surface, wherein the bottom surface is opposite to the top surface, the second lateral surface is opposite to the first lateral surface, and an electrode layer is disposed on the top surface;
a dielectric layer disposed on the bottom surface, the first lateral surface and the second lateral surface; and
a metal layer disposed on the dielectric layer and electrically isolated from the electrode layer.

2. The light emitting diode according to claim 1, wherein the dielectric layer comprises a silicide.

3. The light emitting diode according to claim 2, wherein the dielectric layer comprises a silicon oxide or a silicon nitride.

4. The light emitting diode according to claim 1, wherein the metal layer comprises at least one of silver, gold and aluminum, or an alloy thereof.

5. The light emitting diode according to claim 1, wherein the LED cell comprises:
a substrate;
a first doping layer disposed on the substrate;
a active layer formed on partial surface of the first doping layer; and
a second doping layer disposed on a surface of the active layer.

6. The light emitting diode according to claim 5, wherein the dielectric layer covers the substrate, a lateral surface of the first doping layer, a lateral surface of the active layer and a lateral surface of the second doping layer, and the metal layer covers the dielectric layer.

7. The light emitting diode according to claim 5, wherein the electrode layer comprises:
a first electrode disposed on the surface of the first doping layer not covered by the active layer; and
a second electrode disposed on the surface of the second doping layer.

8. The light emitting diode according to claim 5, wherein the first doping layer is realized by an n-type doping layer, and the second doping layer is realized by a p-type doping layer.

9. A manufacturing method of light emitting diode, comprising:
providing a wafer whose surface has a plurality of adjacent LED cells each having a top surface, a bottom surface, a first lateral surface and a second lateral surface, wherein the bottom surface is opposite to the top surface, the second lateral surface is opposite to the first lateral surface, and an electrode layer is disposed on the top surface;
providing an extendable adhesive and turning over the wafer so that the top surface of each LED cell on the wafer has the extendable adhesive conformably pasted thereon;
performing a cutting process, so that the adjacent LED cells are separated from each other;
extending the extendable adhesive, so that the interval between the separate LED cells is increased to a distance d, wherein d>0;
forming a dielectric layer on the bottom surface, the first lateral surface and the second lateral surface of the LED cells separated by the distance d; and
forming a metal layer electrically isolated from electrode layer on the dielectric layer; and
removing the extendable adhesive.

10. The manufacturing method of light emitting diode according to claim 9, wherein the dielectric layer comprises silicon oxide or silicon nitride or nitrogen oxide silicide.

11. The manufacturing method of light emitting diode according to claim 10, wherein the dielectric layer is formed by chemical vapor deposition process.

12. The manufacturing method of light emitting diode according to claim 9, wherein the metal layer comprises one of silver, gold and aluminum, or an alloy thereof.

13. The manufacturing method of light emitting diode according to claim 12, wherein the metal layer is formed by physical vapor deposition.

14. The manufacturing method of light emitting diode according to claim 13, wherein the metal layer is formed by sputtering or vapor deposition.

15. The manufacturing method of light emitting diode according to claim 9, wherein the cutting process is performed by way of laser, wheel knife or die cutting.

16. The manufacturing method of light emitting diode according to claim 9, wherein the extendable adhesive is a blue tape.
